(19) United States
(12) Patent Application Publication
(10) Pub. No.: US 2010/0012168 A1
(43) Pub. Date: Jan. 21, 2010

(54) QUANTUM DOT SOLAR CELL

(75) Inventors: Mihai N. Mihaila, Bucharest (RO); Viorel-Georgel Dumitru, Ploiesti (RO); Cornel P. Cobianu, Bucharest (RO); Mircea Bercu, Bucharest (RO); Bogdan-Catalin Serban, Bucharest (RO)

Correspondence Address: HONEYWELL INTERNATIONAL INC.;PATENT SERVICES, 101 COLUMBIA ROAD, P O BOX 2245, MORRISTOWN, NJ, 07962-2245, US

(73) Assignee: HONEYWELL INTERNATIONAL, Morristown, NJ (US)

(21) Appl. No.: 12/504,638

(22) Filed: Jul. 16, 2009

Related U.S. Application Data
(60) Provisional application No. 61/081,797, filed on Jul. 18, 2008.

(51) Int. Cl. H01L 31/042; H01L 31/00

(52) U.S. Cl. 136/244; 136/256; 977/774

(57) ABSTRACT

Solar cells and solar cell assemblies that may be tuned for greater sensitivity to particular ranges of energy within the electromagnetic spectrum. In some instances, a solar cell may include a tunable electron conductor that permits greater choices in quantum dots, thereby providing solar cells that can be constructed to utilize a larger fraction of the solar spectrum. In some cases, the electron conductor may include group III nitride-based materials. A solar cell assembly is also disclosed that may include a first quantum dot solar cell and a second quantum dot solar cell. The first and second quantum dot solar cells may be tuned for differing portions of the electromagnetic spectrum.

### PRIORITY

This application claims priority under 35 U.S.C. §119 to U.S. Provisional Application Ser. No. 61/081,797 entitled “QUANTUM DOT SOLAR CELL” filed Jul. 18, 2008, the entirety of which is incorporated herein by reference.

### TECHNICAL FIELD

The disclosure pertains generally to solar cells and more particularly to quantum dot solar cells.

### SUMMARY

The disclosure is directed to solar cells and solar cell assemblies that may be tuned for greater sensitivity to particular ranges of energy within the electromagnetic spectrum. In some instances, a solar cell may include a tunable electron conductor that permits greater choices in quantum dots, thereby providing solar cells that can be designed to utilize a larger fraction of the solar spectrum.

In an illustrative but non-limiting example, a solar cell assembly includes a first quantum dot solar cell and a second quantum dot solar cell that is situated downstream with respect to incident light to the first quantum dot solar cell. The first quantum dot solar cell may be configured to absorb light within a first portion of the electromagnetic spectrum yet be substantially transparent to a second portion of the electromagnetic spectrum. The second quantum dot solar cell may be configured to absorb light within the second portion of the electromagnetic spectrum.

In some instances, the first and second quantum dot solar cells may be substantially transparent to a third portion of the electromagnetic spectrum. The solar cell assembly may, in some cases, further include a third quantum dot solar cell that is situated downstream of the second quantum dot solar cell and that is configured to absorb light within the third portion of the electromagnetic spectrum. In some cases, the first portion of the electromagnetic spectrum may be at a relatively higher energy level (shorter wavelength) than the second portion. Similarly, in some instances, the second portion of the electromagnetic spectrum may be at a relatively higher energy level (shorter wavelength) than the third portion.

In another illustrative but non-limiting example, a solar cell may include a hole conductor, an electron conductor and a quantum dot disposed between the hole conductor and the electron conductor. The electron conductor may include AlGaN. In some cases, the quantum dot may include Cu₂O, but it is contemplated that any other suitable quantum dot may be used.

In another illustrative but non-limiting example, a solar cell may include a hole conductor, an electron conductor and a quantum dot disposed between the hole conductor and the electron conductor. The electron conductor may include InGaN. The quantum dot may be a large dimension quantum dot, but it is contemplated that any other suitable quantum dot may be used.

The above summary is not intended to describe each disclosed embodiment or every implementation of the disclosure. The Description which follows more particularly exemplifies these embodiments.

### BRIEF DESCRIPTION OF THE FIGURES

The following description should be read with reference to the drawings. The drawings, which are not necessarily to scale, depict selected embodiments and are not intended to limit the scope of the disclosure. The disclosure may be more completely understood in consideration of the following detailed description of various embodiments in connection with the accompanying drawings, in which:

FIG. 1 is a schematic diagram of relative energy levels between components of a solar cell;

FIG. 2 is a schematic diagram showing relative energy levels for some materials useful in a solar cell;

FIG. 3 is a schematic diagram of an illustrative solar cell assembly;

FIG. 4 is a schematic diagram of the solar cell assembly of FIG. 3, showing relative energy levels between components of a solar cell assembly;

FIG. 5 is a schematic diagram of a solar cell assembly employing multiple types of quantum dots; and

FIG. 6 is a schematic illustration of a solar cell that includes multiple types of quantum dots.

While the invention is amenable to various modifications and alternative forms, specifics thereof have been shown by way of example in the drawings and will be described in detail. It should be understood, however, that the intention is not to limit the invention to the particular embodiments or examples described. On the contrary, the intention is to cover all modifications, equivalents, and alternatives falling within the spirit and scope of the invention.

### DESCRIPTION

The following description should be read with reference to the drawings, in which like elements in different drawings are numbered in like fashion. The drawings, which are not necessarily to scale, depict selected embodiments and are not intended to limit the scope of the invention. Although examples of construction, dimensions, and materials are illustrated for the various elements, those skilled in the art will recognize that many of the examples provided have suitable alternatives that may be utilized.

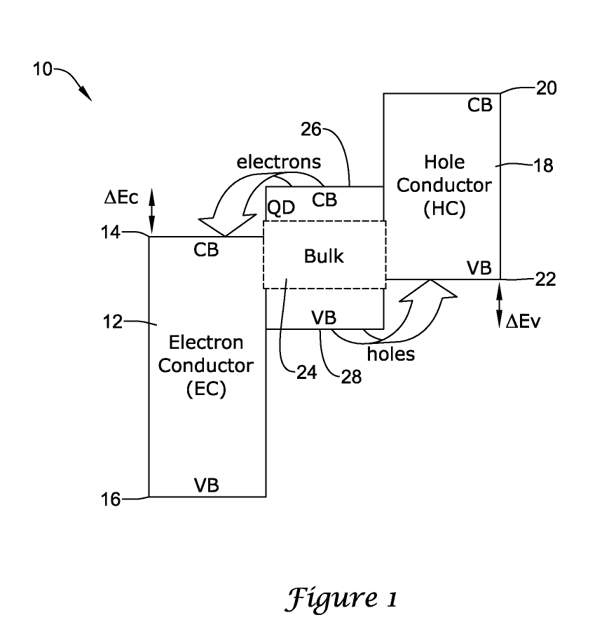

Quantum dot solar cells may include an electron conductor, a hole conductor and a quantum dot. Incident solar energy may be absorbed by the quantum dot. Each photon generates one or more electron-hole pairs. The electrons are transferred to the electron conductor. The quantum dot is regenerated by capture of an electron from the valence band of the hole conductor. This may be considered as equivalent to transfer of a hole from the quantum dot to the hole conductor. For efficient electron transfer, there are particular energy relationships that may be useful, as illustrated in FIG. 1.

FIG. 1 is an energy diagram, illustrating particular relationships between components of a quantum dot solar cell 10. An illustrative solar cell 10 may be seen as including an electron conductor 12 that has a conduction band edge 14 and a valence band edge 16. The illustrative solar cell 10 also includes a hole conductor 18 having a conduction band edge 20 and a valence band edge 22. The illustrative solar cell 10 further includes a plurality of quantum dots, generically illustrated as quantum dot material 24. Quantum dot material 24 has a conduction band edge 26 and a valence band edge 28. It can be seen that a conduction band's offset, or ΔE_{c}, may be defined as a difference between conduction band edge 26 of quantum dot material 24 and conduction band edge 14 of electron conductor 12. Similarly, a valence band's offset, or ΔEᵥ, may be defined as a difference between valence band edge 22 of hole conductor 18 and valence band edge 28 of quantum dot material 24.

It will be appreciated that there are energy relationships that may be useful in constructing quantum dot solar cell 10. It may be useful, for example, that conduction band edge 26 of quantum dot material 24 be at a higher energy level than conduction band edge 14 of electron conductor 12. It may also be useful for valence band edge 28 of quantum dot material 24 be at a lower energy level than valence band edge 22 of hole conductor 18. If hole conductor 18 is a polymer, valence band edge 22 may represent the HOMO (highest occupied molecular orbital) of the polymer. In some instances, solar cell 10 may satisfy the relationship:

E_{g}(QD)>CB(EC)−VB(HC)+ΔE_{c}+ΔEᵥ,

where E_{g}(QD) is the bandgap of the quantum dot material, CB(EC) represents the conduction band edge of the electron conductor, VB(HC) represents the valence band edge of the hole conductor, and ΔE_{c} and ΔEᵥ represent the band offsets defined above and shown in FIG. 1. As can be seen, the above relationship may impact selection of one or more of the electron conductor material, the hole conductor material and/or the quantum dot material and/or quantum dot size.

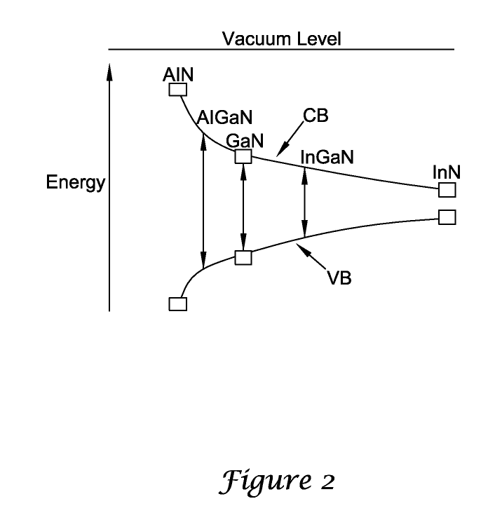

FIG. 2 shows relative values of the CB and VB edges for materials that may be useful in forming an electron conductor for a solar cell. More specifically, FIG. 2 illustrates that group III nitride-based materials may be chosen to have a particular bandgap and/or conduction band edge. It can be seen that, for example, GaN has an intermediate band gap and an intermediate conduction band edge. As can be seen, introducing aluminum (Al) into the GaN material shifts both the conduction and valence band edges, increasing the bandgap. On the contrary, the introduction of indium (In) in the GaN material shifts both the conduction and valence band edges, decreasing the bandgap. It will be appreciated, therefore, that the electron affinity of an electron conductor may be tuned by proper selection of GaN and optionally varying the aluminum content and/or optionally varying the indium content.

In some instances, electron conductor 12 (FIG. 1) may be selected to have a particular electron affinity. As will be discussed subsequently, the electron conductor 12 may be chosen to work well with a particular quantum dot that may be chosen to absorb strongly within a particular wavelength range of the electromagnetic spectrum.

An illustrative but non-limiting example of an electron conductor having a relatively lower electron affinity is AlGaN. While the electron affinity of AlGaN may be modified by altering the aluminum content relative to the gallium content, AlGaN generally has an electron affinity that is less than about 4.2 eV (electron-volts). An illustrative but non-limiting example of an electron conductor having a relatively higher electron affinity is InGaN. While the electron affinity of InGaN may be modified by altering the indium content relative to gallium, InGaN generally has an electron affinity that is greater than about 4.2 eV. Illustrative but non-limiting examples of electron conductors having an electron affinity that is about 4.2 eV include GaN, ZnO and TiO₂.

In some instances, hole conductor 18 (FIG. 1) may be selected, based at least in part, upon the valence band edge 22 (FIG. 1). In some cases, hole conductor 18 may be a conductive polymer, but this is not required. Illustrative but non-limiting examples of suitable polymers include PEDOT:PSS, which is poly(3,4-ethylenedioxythiophene) poly(styrenesulfonate), P3-DDT, which is poly(3-dodecylthiophene), TFB, which is poly(9,9-dioctylfluorene-co-N-(4-(3-methylpropyl)-diphenylamine), P3HT, which is poly(3-hexyl thiophene), and MEH-PPV, which is poly[2,5-dimethoxy-1,4-phenylene-1,2-ethenylene,2-methoxy-5-2-ethylhexyloxy-1,4-phenylene-1,2-ethylene). PEDOT has a HOMO of −5.1 eV, P3-DDT has a HOMO of −5.5 eV, TFB has a HOMO of −5.3 eV, P3HT has a HOMO of −5.24 eV and MEH-PPV has a HOMO of −5.3 eV.

Quantum dot material 24 (FIG. 1) may include quantum dots made from a variety of materials. Illustrative but non-limiting examples of suitable quantum dot materials include materials from Groups II-VI, III-V, or IV-VI materials. Examples of specific pairs of materials for forming quantum dots include but are not limited to MgO, MgS, MgSe, MgTe, CaO, CaS, CaSe, CaTe, SrO, SrS,SrSe, SrTe, BaO, BaS, BaSe, BaTe, ZnO, ZnS, ZnSe, ZnTe, CdO, CdS, CdSe, CdTe, HgO, HgS, HgSe, HgTe, Al₂O₃, Al₂S_{3,} Al₂Se_{3,} Al₂Te_{3,} Ga₂O_{3,} Ga₂S_{3,} Ga₂Se_{3,} Ga₂Te_{3,} In₂O_{3,} In₂S_{3,} In₂Se_{3,} In₂Te_{3,} SiO₂, GeO_{2,} SnO_{2,} SnS, SnSe, SnTe, PbO, PbO₂, PbS, PbSe, PbTe, AlN, AlP, AlAs, AlSb, GaN, GaP, GaAs, GaSb, InN, InP, InAs and InSb. Particular examples of suitable pairs of materials for forming quantum dots include InAs, InP, CdSe, CuO, CuInSe₂ and CuInGaSe₂.

With respect to quantum dot material 24 (FIG. 1), it will be appreciated that different quantum dot materials may be most effective at absorbing light at different energy levels (e.g. wavelengths). The light absorption may be impacted by quantum dot material as well as by quantum dot size. In some instances, quantum dots may be formed of any suitable materials, including those listed above. In some cases, quantum dots may be considered as being small dimension quantum dots. Some quantum dots may be considered as being large dimension quantum dots.

In some instances, a small dimension quantum dot having a strong confinement regime may be useful. A small dimension quantum dot may, in some cases, have a size of less than about 10 nanometers. The particular size may depend at least in part upon the particular material or materials forming the quantum dot. As noted above, particular quantum dots may be selected to function well with a particular material choice for the electron and/or hole conductors.

Illustrative but non-limiting examples of small dimension quantum dots that may be used in combination with particular electron conductors include InAs quantum dots having a size of about 7-8 nanometers, that may be useful with an electron conductor that includes or is otherwise formed from TiO₂, ZnO or GaN. CdSe-based quantum dots having a size of about 2-3 nanometers may be used with the same electron conductors. Additional examples of suitable quantum dots suitable for use with electron conductors such as TiO₂, ZnO or GaN include but are not limited to small dimension quantum dots formed from one or more of InAs, InP, CdSe, CuO, CuInSe₂ or CuInGaSe₂.

For large dimension quantum dots, the appropriate size ranges also depend upon the particular material used to form the quantum dots. In some instances, large dimension quantum dots may be considered as having a size in the range of a few tens of nanometers. In some cases, the electron affinity of the electron conductor may vary with indium content (for InGaN materials) and/or with aluminum content (for AlGaN materials). To illustrate, an InGaN electron conductor having an indium content of about 10 percent may use quantum dots of a first size, while an InGaN electron conductor having an indium content of about 15 percent may use larger-sized quantum dots. Examples of quantum dots that are suitable for use with InGaN electron conductors include but are not limited to large dimension quantum dots formed from one or more of InAs, InP, CdSe, CuO, CuInSe₂ or CuInGaSe₂.

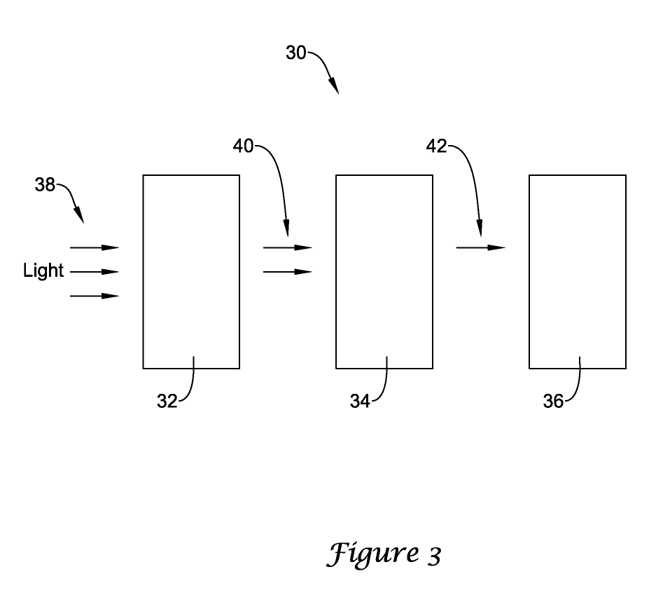

In some instances, two or more solar cells may be combined in a solar cell assembly. In some cases, each of the two or more solar cells may be tuned or otherwise configured to be most sensitive to a different portion of the electromagnetic spectrum, but this is not required. FIG. 3 is a schematic view of an illustrative solar cell assembly 30. The illustrative solar cell assembly 30 includes a first solar cell 32, a second solar cell 34 and a third solar cell 36. While first solar cell 32, second solar cell 34 and third solar cell 36 are schematically shown as distinct, separated elements, it will be recognized that this is for illustrative purposes only. First solar cell 32, second solar cell 34 and third solar cell 36 may each be independently formed and then disposed relative to each other. In some cases, the individual layers forming each solar cell (electron conductor, quantum dot material and hole conductor) may instead be individually formed or otherwise disposed, one atop another, to form solar cell 30. In yet other embodiments, it is contemplated that at least some of the individual layers forming the solar cells may be intermingled, if desired.

It will be appreciated that in some cases, solar cell assembly 30 may only include two distinct solar cell, or four or more distinct solar cells or solar cell layers depending, for example, on what portion or portions of the electromagnetic spectrum the solar cell assembly 30 is designed to be sensitive to.

In some cases, as illustrated, second solar cell 34 may be disposed downstream of first solar cell 32, while third solar cell 36 may be disposed downstream of second solar cell 34. In this regard, downstream is defined relative to a direction of travel of incident light 38. In referring to incident light 38, it will be appreciated that references to light include portions of the electromagnetic spectrum such as visible light, infrared light and ultraviolet light. In some cases, references to light may include a different or wider range of the electromagnetic spectrum.

In the illustrative embodiment of FIG. 3, first solar cell 32 may, in some cases, be configured to absorb light within a first energy range yet be transparent or at least substantially transparent to energy within a second energy range and/or a third energy range and thus may permit light 40 to pass. Light 40 may, for example, include light within the second energy range and/or the third energy range. Second solar cell 34 may, if desired, be configured to absorb light within the second energy range yet be transparent or at least substantially transparent to energy within the third energy range and thus may permit light 42 to pass. Light 42 may, for example, include light within the third energy range. Third solar cell 36 may be configured to absorb light within the third energy range.

In some instances, first solar cell 32 may be sensitive, i.e., may include quantum dots that absorb light having a relatively high energy level (relatively short wavelength). Second solar cell 34 may be sensitive to light having an intermediate energy level (intermediate wavelength). Third solar cell 36 may be sensitive to light having a relative lower energy level (relatively longer wavelength). However, this arrangement is not required in all cases.

In some illustrative embodiments, first solar cell 32 may, for example, include an AlGaN-based electron conductor as well as quantum dots formed from, for example, Cu₂O. In some cases, second solar cell 34 may include an electron conductor that includes or is otherwise formed of gallium nitride, titanium dioxide and/or zinc oxide. Second solar cell 34 may include smaller dimension quantum dots formed from, for example, one or more of InAs, InP, CdSe, CuO, CuInSe₂ or CuInGaSe₂. In some cases, third solar cell 36 may include an InGaN-based electron conductor as well as larger dimension quantum dots formed from, for example, one or more of InAs, InP, CdSe, CuO, CuInSe₂ or CuInGaSe₂.

In some instances, at least two of the first solar cell 32, the second solar cell 34 and/or the third solar cell 36 may each have AlGaN-based electron conductors, each having a different aluminum content and quantum dots that have been appropriately selected so that at least two of the first solar cell 32, the second solar cell 34 and/or the third solar cell 36 may be sensitized to differing portions of the electromagnetic spectrum. In some cases, at least two of the first solar cell 32, the second solar cell 34 and/or the third solar cell 36 may each have InGaN-based electron conductors, each having a different indium content and quantum dots that have been appropriately selected so that at least two of the first solar cell 32, the second solar cell 34 and/or the third solar cell 36 may be sensitized to differing portions of the electromagnetic spectrum. However, this is not required in all embodiments.

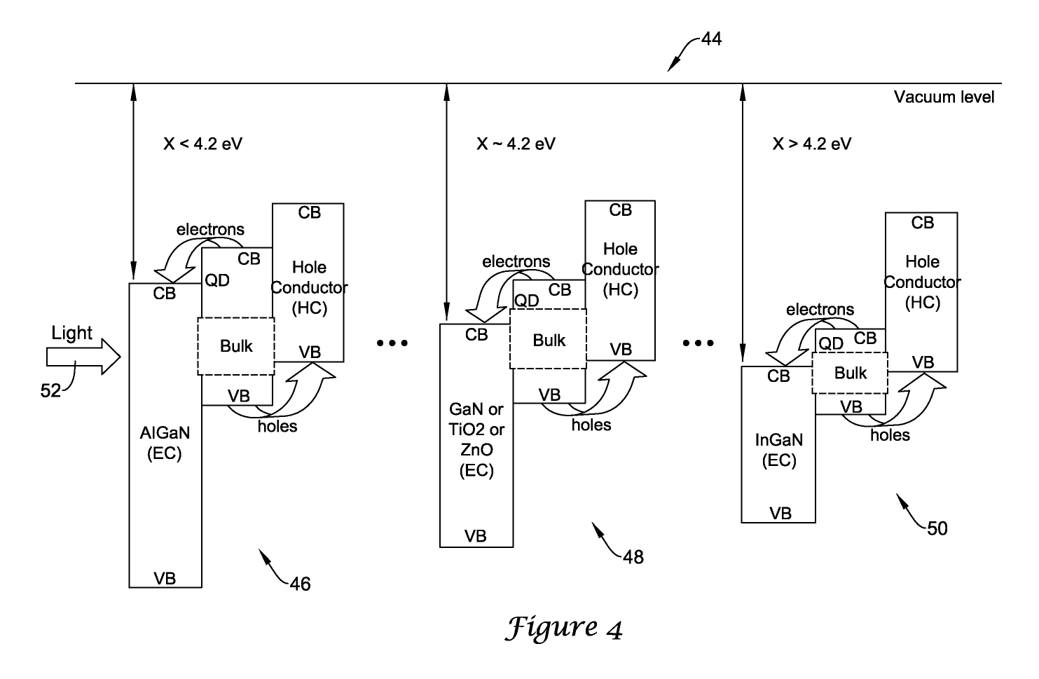

FIG. 4 is a schematic energy diagram of a solar cell assembly 44 that may be considered as an illustrative but non-limiting example of solar cell assembly 30 of FIG. 3. The illustrative solar cell assembly 44 includes a first solar cell 46, a second solar cell 48 and a third solar cell 50. It can be seen that for each of first solar cell 46, second solar cell 48 and third solar cell 50, the relative relationships between conduction bands and valence bands are the same as discussed above with respect to FIG. 1 and thus are not expressly labeled here. As in FIG. 3, the second solar cell 48 is situated downstream of the first solar cell 46, and the third solar cell 50 is situated downstream of the second solar cell 48 relative to incident light 52.

In this particular example, first solar cell 46 is configured to absorb light having a relatively higher energy level and to pass light having other lower energy levels. In the example shown, first solar cell 46 includes an AlGaN-based electron conductor having a relatively lower electron affinity of less than about 4.2 eV. Second solar cell 48 is configured to absorb light having a more intermediate energy level and to pass light having a lower energy level (as higher energy light has already been adsorbed by first solar cell 46). In the example shown, second solar cell 48 includes an electron conductor such as GaN,TiO₂ or ZnO having a more intermediate electron affinity of about 4.2 eV. Third solar cell 50 is configured to absorb light having a relatively lower energy level and, in the example shown, can be seen as including an InGaN-based electron conductor having a relatively higher electron affinity of more than about 4.2 eV.

In some cases, first solar cell 46 may have an AlGaN-based electron conductor and Cu₂O-based quantum dots. First solar cell 46 may have a hole conductor that may be a conductive polymer such as poly(3,4-ethylenedioxythiophene) poly(styrenesulfonate), poly(3-dodecylthiophene), poly(9,9-dioctylfluorene-co-N-(4-(3-methylpropyl)-diphenylamine), poly(3-hexyl thiophene) or poly[2,5-dimethoxy-1,4-phenylene-1,2-ethenylene,2-methoxy-5-2-ethylhexyloxy-1,4-phenylene-1,2-ethylene).

In some instances, second solar cell 48 may have an electron conductor that includes one or more of GaN, TiO₂ or ZnO as well as small dimension quantum dots that are formed from one or more of InAs, InP, CdSe, CuO, CuInSe₂ or CuInGaSe₂. Second solar cell 48 may have a hole conductor that may be a conductive polymer such as poly(3,4-ethylenedioxythiophene) poly(styrenesulfonate), poly(3-dodecylthiophene), poly(9,9-dioctylfluorene-co-N-(4-(3-methylpropyl)-diphenylamine), poly(3-hexyl thiophene) or poly[2,5-dimethoxy-1,4-phenylene-1,2-ethenylene,2-methoxy-5-2-ethylhexyloxy-1,4-phenylene-1,2-ethylene).

In some cases, third solar cell 50 may have an electron conductor that is InGaN-based as well as larger dimension quantum dots that are formed from one or more of InAs, InP, CdSe, CuO, CuInSe₂ or CuInGaSe₂. Third solar cell 50 may have a hole conductor that may be a conductive polymer such as poly(3,4-ethylenedioxythiophene) poly(styrenesulfonate), poly(3-dodecylthiophene), poly(9,9-dioctylfluorene-co-N-(4-(3-methylpropyl)-diphenylamine), poly(3-hexyl thiophene) or poly[2,5-dimethoxy-1,4-phenylene-1,2-ethenylene,2-methoxy-5-2-ethylhexyloxy-1,4-phenylene-1,2-ethylene).

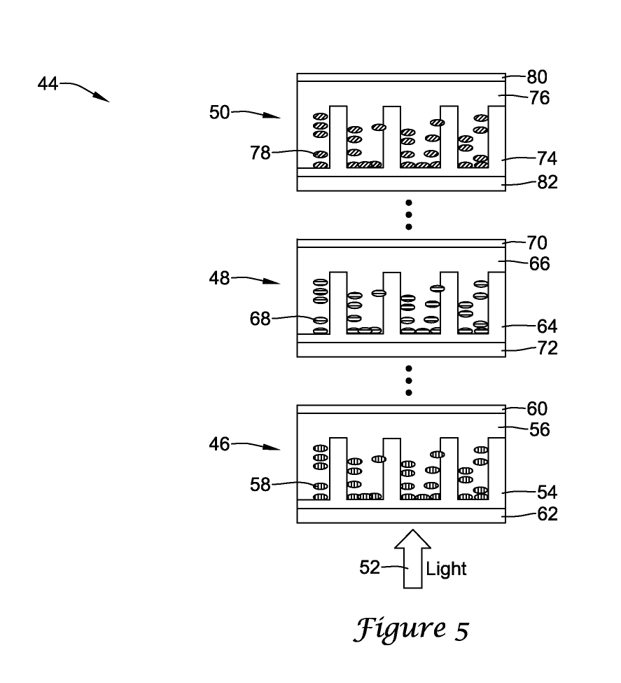

FIG. 5 is a more structural representation of solar cell assembly 44, including first solar cell 46, second solar cell 48 and third solar cell 50. First solar cell 46 can be seen as including an electron conductor 54, a hole conductor 56 and quantum dots 58. In some cases, electron conductor 54 may be AlGaN-based. Quantum dots 58 may be compositionally and/or dimensionally configured to be most sensitive to relatively high energy (short wavelength) light. First solar cell 46 may include electrode layers 60 and 62 formed of any suitable conductive and/or substantially transparent material.

Second solar cell 48 can be seen as including an electron conductor 64, a hole conductor 66 and quantum dots 68. In some cases, electron conductor 64 may be GaN-based. Quantum dots 68 may be compositionally and/or dimensionally configured to be most sensitive to more intermediate energy light. Second solar cell 48 may include electrode layers 70 and 72 formed of any suitable conductive and/or substantially transparent material. Third solar cell 50 can be seen as including an electron conductor 74, a hole conductor 76 and quantum dots 78. In some cases, electron conductor 74 may be InGaN-based. Quantum dots 78 may be compositionally and/or dimensionally configured to be most sensitive to relatively low energy (long wavelength) light. Third solar cell 50 may include electrode layers 80 and 82 formed of any suitable conductive and/or substantially transparent material.

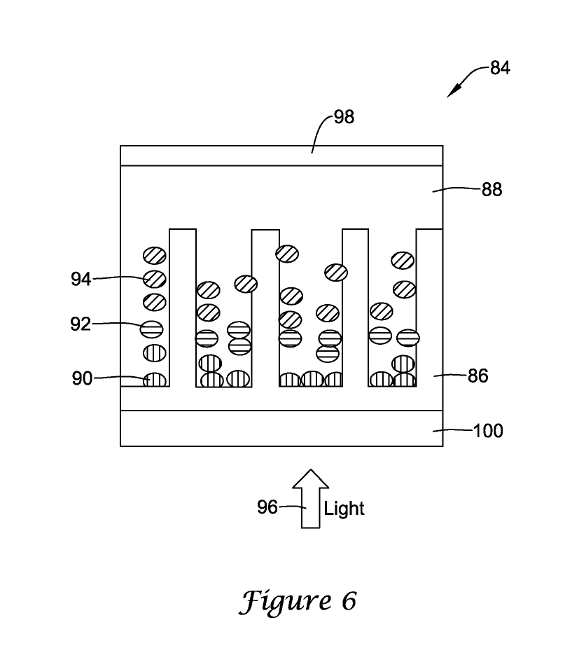

In some cases, it is contemplated that a single solar cell may include multiple types of quantum dots. FIG. 6 is a schematic illustration of a solar cell 84 that includes an electron conductor 86 and a hole conductor 88. In some cases, electron conductor 86 may be InGaN-based, but this is not required. The illustrative solar cell 86 may include one or more of a first group 90 of quantum dots, a second group 92 of quantum dots and/or a third group 94 of quantum dots. Solar cell 86 may include electrode layers 98 and 100 formed of any suitable conductive and/or substantially transparent material.

In the illustrative embodiment, the first group of quantum dots 90 may be sensitive to higher energy light, the second group of quantum dots 92 may be sensitive to intermediate energy light and the third group of quantum dots 94 may be sensitive to lower energy light. In some cases, the quantum dots within each group may be arranged, with respect to a direction of travel of incident light 96, but this is not required. In some instances, the quantum dots within each group may be in a different relative position, or may be randomly intermixed.

In addition, and in some cases, it is contemplated that the electron conductor 86 may include different electron conductor materials and/or different electron conductor features. For example, electron conductor 86 may include a nano-structured electron conductor having nano-features that are based on GaN, InGaN and/or AlGaN materials. Such an electron conductor 86 may be formed, for example, by nano-patterning high quality epitaxial GaN, InGaN and/or AlGaN layers.

In some cases, GaN nano-pores could be formed by self-assembling nano-patterning, employing the use of, for example, an anodized alumina template as a mask for dry etching of GaN using chlorine gas. In some cases, GaN, InGaN and/or AlGaN nanowires and/or core-shell structures, can be formed using MOCVD or other suitable processing techniques. Also, nano-structured electron conductors may be formed by sintering nano-particles and/or nano-wires that were formed using solvothermal techniques. These are just some examples.

The disclosure should not be considered limited to the particular examples described above, but rather should be understood to cover all aspects of the invention as set out in the attached claims. Various modifications, equivalent processes, as well as numerous structures to which the invention can be applicable will be readily apparent to those of skill in the art upon review of the instant specification.

We claim:

1. A solar cell assembly comprising:
a first quantum dot solar cell that is configured to absorb light within a first portion of the electromagnetic spectrum yet be substantially transparent to a second portion of the electromagnetic spectrum;
a second quantum dot solar cell that is configured to absorb light within the second portion of the electromagnetic spectrum;
wherein the second quantum dot solar cell is situated downstream of the first quantum dot solar cell.

2. The solar cell assembly of claim 1, wherein the second quantum dot solar cell is substantially transparent to a third portion of the electromagnetic spectrum.

3. The solar cell assembly of claim 2, further comprising a third quantum dot solar cell that is configured to absorb light within the third portion of the electromagnetic spectrum.

4. The solar cell assembly of claim 3, wherein the third quantum dot solar cell is situated downstream of the second quantum dot solar cell.

5. The solar cell assembly of claim 3, wherein the first quantum dot solar cell is configured to absorb light of a higher energy level than the second quantum dot solar cell.

6. The solar cell assembly of claim 3, wherein the second quantum dot solar cell is configured to absorb light of a higher energy level than the third quantum dot solar cell.

7. The solar cell assembly of claim 1, wherein the first quantum dot solar cell comprises an electron conductor comprising AlGaN.

8. The solar cell of claim 7, wherein the first quantum dot solar cell further comprises Cu₂O-based quantum dots.

9. The solar cell of claim 7, wherein the second quantum dot solar comprises an electron conductor comprising AlGaN, the electron conductor having an aluminum content that is different than an aluminum content of the first quantum dot solar cell electron conductor.

10. The solar cell of claim 9, wherein the second quantum dot solar cell further comprises quantum dots that are compositionally or dimensionally different from the first quantum dot solar cell quantum dots.

11. The solar cell assembly of claim 1, wherein the second quantum dot solar cell comprises an electron conductor comprising one of GaN, TiO₂ or ZnO.

12. The solar cell assembly of claim 11, wherein the second quantum dot solar cell further comprises quantum dots formed from one or more of InAs, InP, CdSe, CuO, CuInSe₂ or CuInGaSe₂.

13. The solar cell assembly of claim 3, wherein the third quantum dot solar cell comprises an electron conductor comprising InGaN.

14. The solar cell assembly of claim 13, wherein the third quantum dot solar cell further comprises quantum dots formed from one or more of InAs, InP, CdSe, CuO, CuInSe₂ or CuInGaSe₂.

15. The solar cell assembly of claim 13, wherein the second quantum dot solar cell comprises an electron conductor comprising InGaN, the electron conductor having an indium content that is different than an indium content of the third quantum dot solar cell electron conductor.

16. The solar cell assembly of claim 15, wherein the second quantum dot solar cell further comprises quantum dots that are compositionally or dimensionally different from the third quantum dot solar cell quantum dots.

17. A solar cell comprising:
a hole conductor;
an electron conductor including a group III Nitride based material; and
a quantum dot disposed between the hole conductor and the electron conductor.

18. The solar cell of claim 17, wherein the electron conductor comprises AlGaN.

19. The solar cell of claim 18, wherein the quantum dot comprising Cu₂O.

20. The solar cell of claim 17, wherein the electron conductor comprises InGaN.

21. The solar cell of claim 20, wherein the quantum dot comprises one or more of InAs, InP, CdSe, CuO, CuInSe₂ or CuInGaSe₂.

22. The solar cell of claim 17, wherein the hole conductor comprises one or more of poly(3,4-ethylenedioxythiophene) poly(styrenesulfonate), poly(3-dodecylthiophene), poly(9,9-dioctylfluorene-co-N-(4-(3-methylpropyl)-diphenylamine), poly(3-hexyl thiophene) or poly[2,5-dimethoxy-1,4-phenylene-1,2-ethenylene,2-methoxy-5-2-ethylhexyloxy-1,4-phenylene-1,2-ethylene).

23. A solar cell comprising:
a hole conductor including a conductive polymer;
an electron conductor including GaN, with an added concentration of aluminum or indium;
a quantum dot disposed between the hole conductor and the electron conductor, the quantum dot formed from a material combination; and
wherein the concentration of aluminum or indium of the electron conductor is dependent on the material combination of the quantum dot.
